(19) United States
(12) Patent Application Publication
(10) Pub. No.: US 2008/0296437 A1
(43) Pub. Date: Dec. 4, 2008

(54) Method and Device to Generate a Transverse Casimir Force for Propulsion, Guidance and Maneuvering of a Space Vehicle

(76) Inventor: Denny Charles Cormier, Newport News, VA (US)

Correspondence Address: Denny Cormier, 12711 Nettles Drive #3, Newport News, VA, 23606, US

(21) Appl. No.: 11/561,839

(22) Filed: Nov. 20, 2006

Related U.S. Application Data
(63) Continuation of application No. 60/738,847, filed on Nov. 22, 2005.

(51) Int. Cl. F03H 5/00; B64G 1/40; H01L 21/00

(52) U.S. Cl. 244/171.5; 438/48

(57) ABSTRACT

Method and device for directly generating a transverse Casimir force comprising a technique for fabricating a microstructure array of non-parallel conducting plates held in place by an insulating material and affixed either to a conducting or insulating substrate are disclosed. As described by the illustrative embodiment, the lateral or transverse force component generated by the present invention works in an orthogonal direction to the normal Casimir force, thereby allowing its use as a means of vectored thrust for precise positioning, guidance, maneuvering and propulsion in a manned or unmanned space vehicle, or any application requiring precise forces.

### CROSS-REFERENCE TO RELATED APPLICATIONS

This application claims priority related to Disclosure Document No. 580518 titled “Method and Apparatus for a Transverse Casimir Force Generator”, filed on Jun. 16, 2005. Furthermore, this application claims priority from Provisional Application No. 60/738,847 filed Nov. 22, 2005, which is hereby incorporated by reference in its entirety

### FIELD OF THE INVENTION

The present invention involves methods, microstructures and devices for generating a transverse Casimir force by using an array of non-parallel conducting plates and an intervening dielectric or semiconductor material to provide propulsion in manned or unmanned space vehicles.

### BACKGROUND OF THE INVENTION

Although the method and apparatus of the present invention utilizes some of the basic theoretical principles developed by Hendrick B. G. Casimir in 1948, it involves several new concepts as well. It is therefore helpful to briefly summarize the background theoretical and experimental work that underlies the method and device of the present invention.

Adapting basic theoretical relationships of Heisenberg's Uncertainty Principle, Dr. Casimir predicted that an attractive force should exist between two parallel conducting plates due to the existence of a zero-point energy, originally proposed by Max Planck and Albert Einstein about 1911. Specifically, this Casimir force or “effect” results from an imbalance in the formation of virtual particle-antiparticle pairs arising from the vacuum zero-point energy, even at absolute zero—hence the term “zero-point energy”.

In general, zero-point energy virtual particles continually bombard any set of conducting plates in a uniform manner. But, if the distance between any two conducting plates is small enough, longer wavelength virtual particles are excluded from forming within this gap. Because of this restriction, the overall number of virtual particles forming between the two plates is reduced, causing a net “pressure” to develop from the impact of extra virtual particles impinging on the outside of the plates. In a related way, fluctuations of charges within molecules can cause transient dipoles, which result in an attractive Van der Waals force. However, the Casimir force arises from vacuum zero-point energy virtual-particle formation, instead of interaction with molecular dipoles.

In explicit terms, the magnitude of the Casimir force, F_{c}, for perfectly conducting parallel plates having a vacuum between them, can be expressed as:

$${F}_{c} = \frac{{π}^{2} ℏ cA}{240 {a}^{4}} \qquad Equation 1$$

where [symbol] is the reduced Planck constant, c is the speed of light, A is the area of the plates and a is the distance between the plates. Actual measurements of the Casimir force have recently been made by Steve K. Lamoreaux of Los Alamos National Laboratory and by Umar Mohideen of the University of California at Riverside. These measurements agree with Dr. Casimir's original predictions to within 5%. Dr. Mohideen and his colleagues have also measured the transverse (sometimes referred to as “lateral”) Casimir force to similar accuracies (see REFERENCES).

In the present invention, however, non-parallel conducting plates are used instead or parallel ones. FIG. 1 shows an illustrative embodiment of the present invention whereby an array of non-parallel conducting plates provides the mechanism for generating a transverse Casimir force acting in an orthogonal direction to the normal Casimir force. A detailed construction of the force components, generated by the present invention, is portrayed in FIG. 2, which demonstrates that F_{c} in Equation 1 represents the vertical component of the Casimir force, Fᵥ, in the case of non-parallel conducting plates at any point along the distance x₀ to x₁. Because of the trigonometric identity between Fᵥ and the corresponding transverse force component, Fₜ, at any point, this transverse force must therefore be Fₜ=Fᵥ tan θ, where θ is the angle subtended by the non-parallel plates at their constructed intersection, or Fᵥ and the normal Casimir force, Fₙ.

From FIG. 3, it is clear that the effective area, A, of each lower plate is LΔx, where Δx=x₁−x₀. Consequently, by taking the limit of Equation 1 with respect to x, the total transverse force, F_{T}, for each segment can be found by substituting (a+x tan θ) for the varying separation, a(x), of the non-parallel plates as a function of x between x₀ and x₁, such that a is the minimum plate separation at x₀, as shown in FIG. 2. Thus, by using the following integral expression in Equation 2, the total generated transverse Casimir force, F_{T}, per segment can be found:

$${F}_{T} = {\int }_{{x}_{0}}^{{x}_{1}} \frac{{π}^{2} ℏ cL tan θ}{240 {( a + x tan θ )}^{4}} d x . \qquad Equation 2$$

By letting x₀=0, then x₁=Δx, and consequently evaluation of the definite integral in Equation 2 yields the following expression for F_{T} in terms of Δx:

$${F}_{T} = \frac{{π}^{2} ℏ cL}{720} [ {a}^{- 3} - {( a + Δ x tan θ )}^{- 3} ] . \qquad Equation 3$$

As expected in the case of parallel plates, where θ=0, the magnitude of the total transverse Casimir force, F_{T}, in Equation 3 falls to zero. Numerical analysis and measurements by the inventor have demonstrated that a value of θ≈10° provides a nearly optimal level of F_{T} with minimal nonlinear Casimir effects, while allowing fabrication of the non-parallel plate array in FIG. 1 using standard techniques such as differential or reactive-ion etching, molding, deposition or ablation. For most applications, where the value of Δx>>a, it can be seen from Equation 3 that F_{T} is nearly proportional to 1/a³.

### SUMMARY OF THE INVENTION

Some embodiments of the present invention provide a method and device for directly generating a transverse Casimir force, by incorporating microstructure fabrication techniques to create a non-parallel conducting plate array. Microstructures of this type can be fabricated from semiconductor or insulator substrates. The magnitude of the transverse Casimir force can be altered by changing the angle of the non-parallel plates in the microstructure array, or by changing the electrical properties of the insulating or semiconductor layer between the non-parallel plate array. In addition to propulsion, guidance and maneuvering of space vehicles, some applications of the present invention include precision measurement, vehicle stabilizers, gyroscopes, artificial gravity generators, corrective force generators, energy conversion systems, and other devices requiring very constant, precisely controlled forces.

### BRIEF DESCRIPTION OF THE DRAWINGS

FIG. 1 depicts a cross-sectional view of the present invention showing an illustrative embodiment of its non-parallel plate array microstructure for generating a transverse Casimir force and the resulting summated force-vector components.

FIG. 2 depicts diagrammatically a detailed resolution of the transverse Casimir force components directly generated by the effect of normal Casimir force vectors on a non-parallel plate microstructure segment by using an intervening dielectric or semiconductor material in this illustrative embodiment of the present invention.

FIG. 3 depicts a three-dimensional portrayal of the present invention demonstrating physical construction of the force-directing non-parallel plate array and showing a cross-section of the transverse Casimir force-generating microstructure in this illustrative embodiment.

FIG. 4 depicts a magnified cross-sectional illustrative embodiment of the present invention wherein a semiconductor PN-junction has been used instead of said insulating barrier layer, thereby allowing the effective conducting-plate separation to be rapidly changed electronically to precisely vary or switch the directly-generated transverse Casimir force.

FIG. 5 depicts in diagrammatic form an illustrative embodiment of a space vehicle of the present invention propelled by said transverse Casimir force-generator microstructure device for control, maneuvering, artificial gravity and vectored thrust in a manned or unmanned space vehicle.

### DETAILED DESCRIPTION

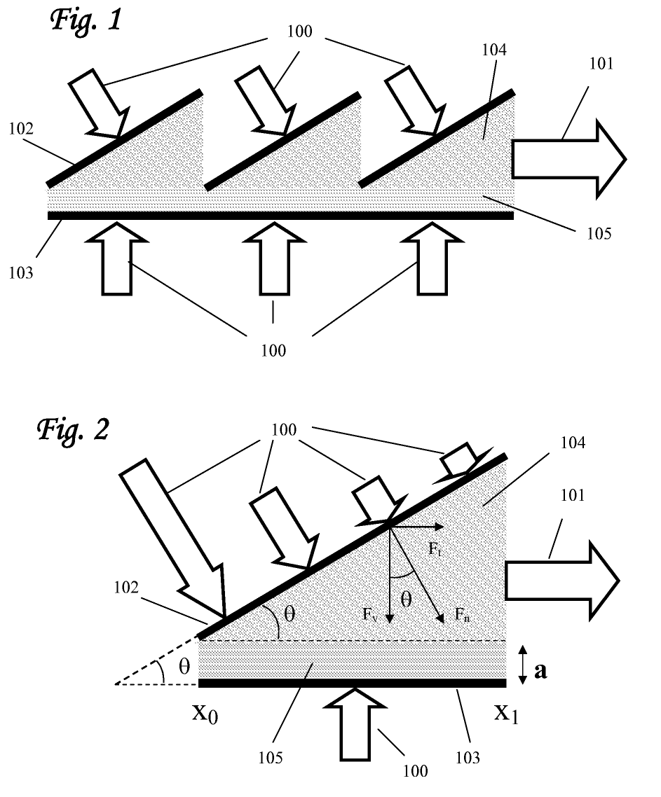

Applying the aforementioned theory relating to the Casimir effect, the present invention directly generates a transverse force vector 101 acting along an orthogonal (horizontal) direction to normal Casimir forces 100 directed downward on the non-parallel conducting plate array 102 and upward on the bottom conducting plate 103 shown in FIG. 1. This arrangement of the non-parallel conducting plate array 102 shown in FIG. 1 forms a “sawtooth” configuration, and directly converts the normal Casimir force into a transverse or lateral Casimir force component 101 by cumulative addition along each successive microstructure stage comprising a plurality of prismatic-shaped stages in this illustrative embodiment of the present invention.

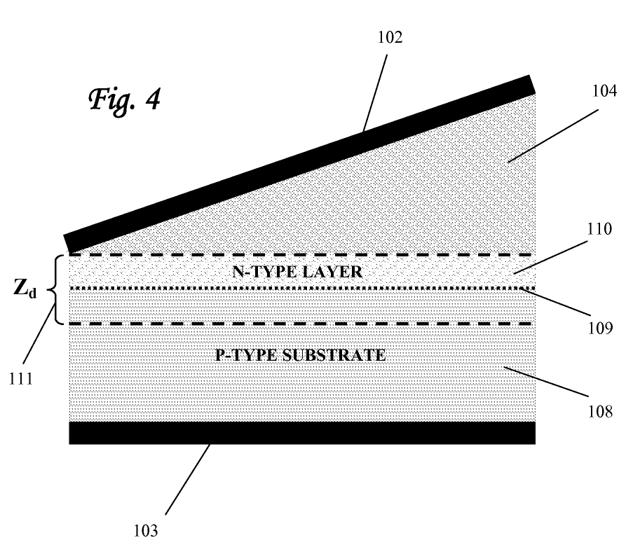

A micro-thin insulating barrier layer 105 having thickness, a, in the sub-micron range separates the non-parallel conducting plate array 102 and the bottom conducting plate 103 to directly convert a component of the normal Casimir force 100 to a transverse direction 101. Fabrication of the insulating barrier layer 105 can be accomplished with standard microstructure and integrated circuit techniques by using chemical deposition in conjunction with photoresist or photomasking preparations, or by vacuum film-deposition or similar methods (e.g., oxidation, precipitation or sputtering) on various types of substrates including metal oxides, silicon dioxide, semiconductors, organic polymers and silicones. Alternatively, the insulating barrier layer 105 can be formed by using a PN-junction layer to permit electronic modulation or switching of this microstructure's effective thickness, as shown in FIG. 4, and as described herein in greater detail.

Shaping of each non-parallel conducting plate array 102 can be accomplished by repetitively using sequential photomasking and differential etching methods, or by repetitively applying reactive ion etching to form a plurality of prismatic microstructure segments. The intervening dielectric 104 can be fabricated using either deposition, differential or reactive-ion etching, or other ablative methods in conjunction with photomasking techniques. Said dielectric not only provides mechanical stabilization, support and cohesion with the insulating barrier layer 105, but can also alter the magnitude or even reverse the direction of said transverse Casimir force vector 101 when made from special insulators, semiconductors or photo-resistive materials, or by subjecting it to an electrical field or electromagnetic radiation.

Portrayed in FIG. 2 is a detailed decomposition of the Casimir force components, Fₙ, Fₜ, and Fᵥ, demonstrating how these forces are directly generated by the present invention and their interaction with a non-parallel conducting plate segment 102. In this illustrative embodiment; the intervening dielectric 104 of the present invention alters a portion of the virtual-particle resonant modes, thereby modifying the effect of the normal Casimir forces 100 with a corresponding change in the resultant transverse Casimir force 101. Fₙ represents the normal Casimir force vector 100 acting at the point indicated along the non-parallel conducting plate 102, which subtends an angle θ with the bottom plate 103. Because the normal Casimir force varies greatly with separation between plates 102 and 103, its magnitude decreases significantly from point x₀ to x₁ as shown in FIG. 2. At x₀, the magnitude of the Casimir force is greatest because plates 102 and 103 are only separated by thickness, a, of said insulating barrier layer 105.

The vertical component of the Casimir force, Fᵥ, has a magnitude that is governed by Equation 1. Since Fᵥ is also equal to Fₙ cos θ, by trigonometric identity, then the local transverse Casimir force component, Fₜ, must be Fₙ sin θ, or Fᵥ tan θ. Hence, the magnitude of the total transverse Casimir force vector 101 can be found by numerical integration of all the force elements, Fₜ, over interval x₀ to x₁. Explicitly, the magnitude of the transverse Casimir force vector 101, for n microstructure segments, or nF_{T}, in the non-parallel conducting plate array 102, has been formulated in Equation 3, which can be used in computer-aided-design (CAD) of said microstructures for a space vehicle.

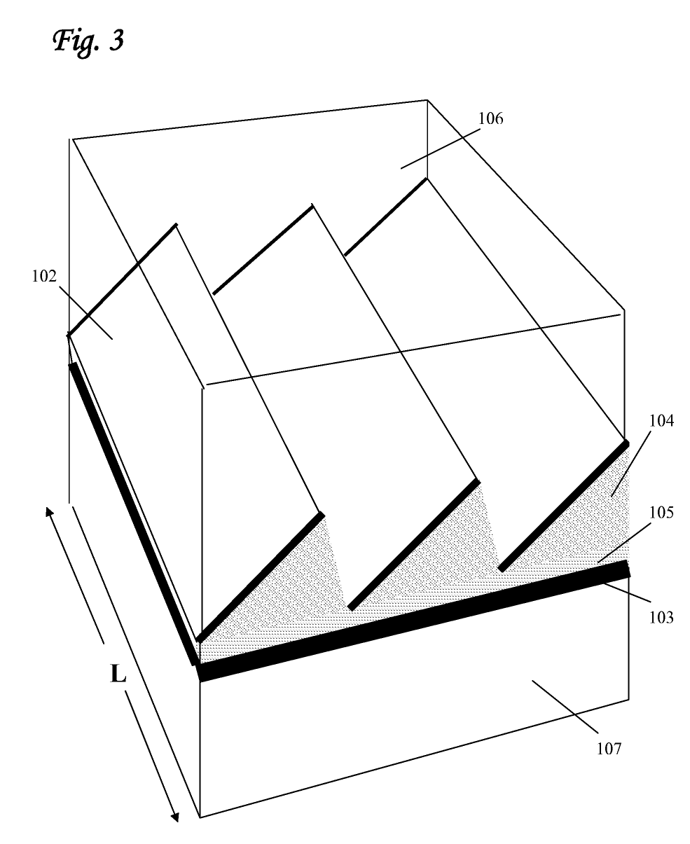

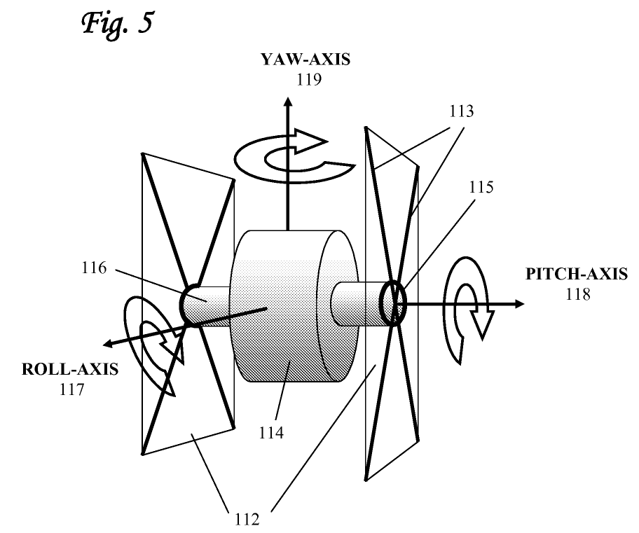

Physical layout for the force-generating microstructure of the present invention can be seen in FIG. 3 as a three-dimensional cross-sectional rendering. This illustrative example of the present invention demonstrates physical means and methodology for constructing a plurality of force-directing microstructure segments comprising said non-parallel conducting-plate array 102 necessary to directly generate said transverse Casimir force vector 101. Length, L, shown in FIG. 3, can be extended as needed to increase the magnitude of the transverse Casimir force vector 101 to the desired level. This entire microstructure assembly can be constructed on a rigid base layer 107, which not only provides physical support for the bottom conducting plate 103, but also furnishes a means for attaching a plurality of prismatic microstructure arrays and non-parallel conducting plates 102 to a larger framework, thereby providing a means of thrust for maneuvering, guidance and propulsion in a space vehicle as described herein and shown in FIG. 5.

Furthermore, FIG. 3 depicts an upper insulating matrix 106 that provides both physical support and protection for said non-parallel conducting plate array 102. Said upper insulating matrix can be fabricated by molding or deposition techniques. Insulating matrix 106 can consist of polymer or other durable insulating materials. Furthermore, each microstructure segment in the non-parallel conducting plate array 102 can have an effective force-generating area, A, where A=LΔx, and Δx=x₁−x₀. Hence, a plurality of microstructure segments can be bonded as a unit thereby causing the magnitude of the directly generated transverse Casimir force vector 101 to be increased as needed either by extending length L or by adding more microstructure segments to the non-parallel conducting plate array 102.

An enlarged view of said non-parallel plate microstructure segment of the present invention has been portrayed in FIG. 4 to illustrate a means and method for switching said transverse Casimir force 101 into “on” or “off” states. In this illustrative embodiment of the present invention, a PN-junction semiconductor structure has been utilized for the insulating barrier layer 105 by starting with a P-type semiconductor substrate 108, where either silicon or germanium are typically used for this purpose. By employing standard semiconductor fabrication techniques, a thin N-type semiconductor layer 110 is thereupon gas-diffused into the P-type layer 108 to form the PN-junction layer 109 depicted in FIG. 4. Due to charge migration, a depletion zone 111 of thickness Z_{d} forms around said PN-junction layer 109, which lacks free charge carriers and therefore acts like an insulator. The N-type layer 110 is in electrical contact with the top non-parallel conducting plate 102 to permit application of external biasing voltages to said PN-junction layer 109.

Because the N-type layer 110 is very thin, the depletion zone 111 occupies its entire width at zero bias (i.e., absence of external voltage), and causes its electrical resistance to be very high throughout. Z_{d} widens even further under conditions of reverse electrical bias, when the potential difference remains below breakdown voltage. Hence, in a zero-biased or reverse-biased condition, the insulating depletion zone 111 becomes wide enough to encompass the entire N-type layer 110, whereas the P-type substrate below the depletion zone 111 remains highly conductive. Consequently, the comparatively large width of Z_{d} becomes the effective width, a, of the insulating barrier layer 105, thereby causing the transverse Casimir force 101 to drop to a very low magnitude, or to essentially be switched to an “off” state.

Conversely, when a forward bias voltage is applied to the PN junction 109 (e.g., about 0.6 volts for silicon PN-junctions), the depletion zone 111 becomes flooded with extra charge carriers, making its width shrink, and flooding the top portion of the N-type layer 110 with charge carriers (i.e., electrons). As a result, the top portion of said N-type layer 110 now acts like a conductor, and the effective width, a, of the insulating barrier layer 105 narrows to just a few atomic diameters. This shrinking of the insulating barrier layer 105 to an extremely narrow width produces a tremendous increase in the generated transverse Casimir 101 force effectively switching it into the “on” state.

Thus, utilization of the PN-junction 109 in the present invention allows the directly-generated transverse Casimir force 101 to be electronically switched from an “off” to an “on” state by application of a forward-biasing external voltage across non-parallel conducting plates 102 and 103. An additional benefit of said PN-junction fabrication technique described herein is that it minimizes warping or distortion of the microstructure by unwanted Casimir forces during formation of the top non-parallel conducting plate 102 and the intervening dielectric structure 104. Moreover, electronic switching of said transverse Casimir force 101 means that a space vehicle can be constructed with maneuvering, guidance and propulsion systems without the need for moving parts, thereby greatly increasing the reliability and lifetime of these systems.

FIG. 5 depicts an illustrative embodiment for applying said transverse Casimir force 101 described herein as an apparatus to provide maneuvering, guidance and propulsion for a manned or unmanned space vehicle. Casimir drive panels 112 are comprised of a plurality of said microstructures shown in FIG. 1 sufficient to furnish said vehicle with vectored thrust for maneuvering, guidance and propulsive systems. Most of the microstructure units on said drive panels 112 are mounted in the same direction to provide vectored thrust to propel the vehicle's fuselage 114. A smaller amount of said Casimir force generating units can be mounted around the perimeter of the Casimir drive panels 112 to provide thrust for guidance and maneuvering. Aerodynamic design is not necessary because there are no lift or drag forces in outer space.

To add stability and reliability, the Casimir drive panels 112 are held in place on both sides by supporting struts 113, which attach to said vehicle's axle-pivots 115, thereby allowing rotation around axles 116 and corresponding transfer of maneuvering and propulsive forces to said vehicle's fuselage 114 via said axles 116. Because the transverse Casimir force 101 can be electronically switched, some force-generating microstructures of the present invention can be oriented in different directions at appropriate locations on the Casimir drive panels 112 to control roll, pitch and yaw maneuvers.

In the case of pitch-maneuvers, tandem microstructure devices depicted in FIG. 1 having electrically common bottom conducting plates 103 can be mounted along the perimeter of the Casimir drive panels 112. Accordingly, direction of said mounted microstructure devices producing the transverse Casimir force 101 is reversed at opposite ends of the Casimir drive panels 112, thereby creating a torque around the pitch-axis 118 when switched “on” electronically by applying a forward bias to all desired PN-junctions 109.

There are two ways to initiate maneuvers around the roll-axis 117 or yaw-axis 119. For roll-maneuvers, the Casimir drive panels 112 can be rotated in opposite directions on axle-pivots 115, thereby providing torque around the roll-axis 117; alternatively, microstructures for generating the transverse Casimir force 101 on opposite drive panels 112 and pointing in opposite directions can be switch “on” electronically without the need for rotation of Casimir drive panels 112 around axle-pivots 115. Similarly, yaw-maneuvers can be executed in virtually the same manner as roll-maneuvers because of the radial symmetry of these axes around the pitch-axis 118.

As mentioned previously herein, propulsive thrust to accelerate said vehicle's fuselage 114 is provided by mounting a majority of said force-generating microstructure devices of the present invention in the same direction throughout each Casimir drive panel 112. However, sections of said force-generating devices can be selectively switched “on” or “off” independently of each another to provide varying levels of propulsive thrust or trim settings for either manned navigation or unmanned computer-controlled guidance of said space vehicle of the present invention.

The only onboard electrical power required to propel an unmanned version of the present invention would be for energizing onboard computer avionics, telemetry systems and motors to occasionally rotate the Casimir drive panels 112 and to furnish voltage for switching the microstructure PN-junctions 109 into the “on” state. In a manned version of the present invention, power would also be needed for life-support systems within the vehicle's fuselage 114. Because the present invention utilizes direct-generation of the Casimir force into thrust, no reaction mass is required for maneuvering, guidance or propulsion of said space vehicle. An additional feature of the said space vehicle's design is that it can be set into a constant rotation around pitch-axis 118 to create an artificial gravity for a crew around the inner perimeter of the vehicle's fuselage 114.

All the above examples represent an important advance in the field of the present invention, especially in applications dealing with positioning, guidance, maneuvering and propulsion systems for both manned and unmanned space vehicles, plus any application requiring application of precise forces. Furthermore, the concept of a transverse Casimir force generator permits entirely new engineering modalities including applications involving weights and measures, aircraft and satellite guidance, propulsive drives, and power conversion systems.

It is to be understood that the above-described embodiments and variations thereon are merely illustrative of the present invention and that many additional variations can be devised by those skilled in the art without departing from the scope of the invention. It is therefore intended that such variations be included within the scope of the present invention and its equivalents.

### REFERENCES

Buks, E. and Roukes, M. L., “Quantum physics: Casimir force changes sign”, Nature 419, Sep. 12, 2002, pp. 119-120.
Chan, H. B. et al., “Quantum Mechanical Actuation of Microelectromechanical Systems by the Casimir Force”, Science vol. 291, pp. 1941-1944, Mar. 9, 2001, with corrections.
Chen, F. and Mohideen, U., “Demonstration of the Lateral Casimir Force”, Phys. Rev. Lett. 88 101801 (Feb. 25, 2002), http://link.aps.org/abstract/PRL/v88/e101801
Einstein, A. and Hopf, L., Ann. Phys., 33, 1096 (1910a); Ann. Phys., 33, 1105 (1910b).
Forward, R. L., “Extracting Electrical Energy From the Vacuum by Cohesion of Charged Foliated Conductors,” Phys. Rev. B, 30(4), 1700-1702 (August 1984), http://www.calphysics.org/articles/Forward1984.pdf.
Forward, R. L., “Apparent Endless Extraction of Energy From the Vacuum by Cyclic Manipulation of Casimir Cavity Dimensions,” Proc. NASA Breakthrough Propulsion Physics Wkshp., Cleveland, Ohio (Aug. 12-14, 1997).
Lambrecht, A. “The Casimir effect: a force from nothing”, Physics World September 2002, http://physicsweb.org/article/world/15/9/6.
Lamoreaux, S. K., “Demonstration of the Casimir Force in the 0.6 to 6 μm Range”, Phys. Rev. Lett. 78, 5-8 (1997), http://link.aps.org/abstract/PRL/v78/p5.
Lamoreaux, S. K., “Resource Letter CF-1: Casimir Force,” Am. J. Phys., 67(10), 850-861 (October 1999).
Milonni et al., “Casimir Forces,” Contemporary Physics, 33(5), 313-322 (1992).
Mohideen, U. and Anushree Roy, “Precision Measurement of the Casimir Force from 0.1 to 0.9 .mu.m”, Phys. Rev. Lett., vol. 81, No. 21, pp. 4549-4552, Nov. 23, 1998.
Van Enk, S. J., “Casimir torque between dielectrics”, Phys. Rev. A, vol. 52, No. 4, pp. 2569-2575, October 1995.
Xin-zhou Li, et al., “Attractive or repulsive nature of the Casimir force for rectangular cavity”, Phys. Rev. D, vol. 56, No. 4, pp. 2155-2162, Aug. 15, 1997.

What I claim is:

1. A propulsive device for directly generating a transverse Casimir force by means of a plurality of microstructures to provide vectored thrust for a space vehicle comprising:
a flat, rigid, supporting base, consisting of either conducting or insulating material polished to optical-flat quality, upon which is deposited a layer of highly conductive metal forming a bottom conducting plate;
a semiconductor substrate to support a plurality of microstructures, deposited or affixed to and in electrical contact with said bottom conducting plate, upon which is a grown, deposited or diffused a heavily-doped P-type semiconductor layer;
on top of said P-type semiconductor layer is a grown, deposited or diffused, thin N-type semiconductor layer, which forms a PN-junction and acts as an insulating barrier layer;
upon said N-type semiconductor layer is a plurality of angled, prismatic or tapered insulating dielectric microstructures arrayed in a “sawtooth” configuration, which have been deposited by gaseous or chemical means and etched by using photolithographic techniques;
an array of angled (non-parallel) conducting plates, deposited by gaseous or chemical means, upon the angled portion of said “sawtooth” array of insulating dielectric microstructures, and making electrical contact at one end of each insulating dielectric microstructure with said N-type semiconductor layer underneath;
a protective insulating matrix, deposited by physical, gaseous or chemical means, which coats said angled (non-parallel) conducting plates to provide stability and rigidity for the plurality of microstructure arrays underneath, thereby shielding them from radiation, physical abrasion or impact.

2. The propulsive device of claim 1 wherein said direct-generating transverse Casimir force microstructure further comprises generation of the lateral Casimir force.

3. The propulsive device of claim 1 wherein an insulating barrier layer, consisting of materials such as silicon dioxide or sapphire, is used instead of said N-type semiconductor layer to permit a microstructure that constantly generates a transverse Casimir force;

4. The propulsive device of claim 1 wherein the N-type layer is electrically connected to the top non-parallel conducting plate of said microstructure to permit switching of said N-type layer into a highly-conductive “on” state by means of an external forward-bias voltage imposed across said microstructure's non-parallel conducting plates.

5. The propulsive device of claim 1 wherein said insulating dielectric further comprises material capable of modifying or reversing said transverse Casimir force when subjected to an electrical field induced by a voltage imposed across said non-parallel conducting plates.

6. The propulsive device of claim 1 wherein said insulating dielectric further comprises a material capable of modifying or reversing said transverse Casimir force when subjected to electromagnetic radiation ranging in frequency from radio waves to gamma rays.

7. The propulsive device of claim 1 wherein said insulating matrix further comprises a polymer impregnated with a material to provide shielding for said microstructures from electromagnetic and particle radiation.

8. The propulsive device of claim 1 wherein said insulating matrix further comprises a polymer impregnated with a material to provide increased strength for protection of said microstructures against physical abrasion and impact.

9. A method for fabricating a microstructure device to directly generate a transverse Casimir force comprising the steps of:
(a) defining and forming a rigid glass, ceramic, metallic or polymer base layer having a substantially uniform thickness and polished to optical flatness, and depositing a thin layer of highly conductive metal upon it by means of chemical (e.g., precipitation) or gaseous (e.g., sputtering) deposition;
(b) making an insulating or semiconductor substrate by chemical (e.g., precipitation) or gaseous (e.g., sputtering) deposition, on top of said highly conductive metallic layer;
(c) coating said insulating or semiconductor substrate with an insulating dielectric layer by either chemical or gaseous deposition means;
(d) forming said insulating dielectric layer into angled, prismatic or tapered microstructures by differential etching or reactive ion etching and photolithographic masking to create an array consisting of a plurality of said microstructures and exposing said substrate underneath at the narrow end of each microstructure;
(e) coating the top surface of said microstructures with a highly conductive metallic layer by means of chemical (e.g., precipitation) or gaseous (e.g., sputtering) deposition and electrically contacting the underlying substrate at the narrow end of each microstructure;
(f) coating entire said microstructure array with a protective insulating matrix by physical, chemical or gaseous deposition for the purpose of protecting said microstructures from physical or radiation damage.

10. The method in claim 9 wherein a semiconductor substrate is made by adhering a pre-formed intrinsic or P-type semiconductor wafer on top of and in electrical contact with said highly conductive metallic layer underneath, instead of depositing said semiconductor layer by chemical or gaseous deposition methods as described in step (b).

11. The method in claim 10 wherein a PN-junction is formed or grown on top of said P-type semiconductor substrate by using said standard gaseous diffusion methods to form a thin N-type semiconductor layer on top of said P-type substrate having insulating properties under conditions where there are no external electrical fields or voltages.

12. The method in claim 9 wherein a thick highly-doped P-type semiconductor layer is further formed or grown on top of said semiconductor substrate described in step (b) by standard gaseous diffusion methods used in the integrated-circuit industry.

13. The method in claim 12 wherein a PN-junction is formed or grown on top of said highly-doped P-type semiconductor layer by using said standard gaseous diffusion methods to form a thin N-type semiconductor layer on top of said P-type layer having insulating properties under conditions where there are no external electrical fields or voltages.

14. A space vehicle for transporting people and cargo outside the earth's atmosphere propelled by vectored thrust from said direct-generation transverse Casimir force microstructure devices comprising:
an array of said direct-generation transverse Casimir-force propulsive devices affixed onto two Casimir drive panels and mounted in various directions to permit maneuvering and guidance, plus vectored thrust for forward or reverse propulsion when switched from “off” to “on” states;
two or more supporting struts fabricated from durable rigid material to prevent deformation of said Casimir drive panels under forces created by rotation, acceleration or vibration, and to transmit generated thrust to the space vehicle's axle-pivot for maneuvering, guidance and propulsion;
two axles attached to said space vehicle's fuselage to house an electromechanical drive system for rotating each of said two Casimir drive panels independently around each axle-pivot, and for supplying electrical power to switch said direct-generation transverse Casimir-force propulsive devices “on” or “off” for maneuvering, guidance and propulsion;
an airtight, shielded and pressurized fuselage containing a life-support system and guidance and navigation systems capable of conveying crew, passengers and cargo through outer space by means of said direct-generation transverse Casimir-force propulsive devices.

15. The space vehicle in claim 14 wherein said transverse Casimir-force propulsive devices for pitch-axis maneuvers are located in the periphery of the Casimir drive panels and can be activated by means of an “on” forward-bias voltage.

16. The space vehicle in claim 14 wherein roll-axis and yaw-axis maneuvers can be accomplished by differential switching of said transverse Casimir-force propulsive devices situated at any location on said Casimir drive panels, or by mechanical rotation of the Casimir drive panels around their corresponding axle-pivots.

17. The space vehicle in claim 14 wherein forward or reverse thrust can be accomplished by equal thrust generation from the majority of said transverse Casimir-force propulsive devices by switching them into the “on” state or by rotation of the Casimir drive panels into the desired directions around their corresponding axle-pivots.

18. The space vehicle in claim 14 wherein an artificial gravity can be created in the periphery of said vehicle's fuselage through initiation of a constant rotation around the pitch-axis by the transverse Casimir-force propulsive devices located in the periphery of said Casimir drive.

19. The space vehicle in claim 14 wherein its maneuvering, guidance and navigational systems in its fuselage are further capable of operation under computer control for either manned or unmanned space flight.
